(19) United States
(12) Patent Application Publication
(10) Pub. No.: US 2019/0115353 A1
(43) Pub. Date: Apr. 18, 2019

(54) LAYER TRANSFERRED FERROELECTRIC MEMORY DEVICES

(71) Applicant: Intel Corporation, Santa Clara, CA (US)

(72) Inventors: Kevin P. O'Brien, Portland, OR (US); Brian S. Doyle, Portland, OR (US); Kaan Oguz, Beaverton, OR (US); Charles C. Kuo, Hillsboro, OR (US); Mark L. Doczy, Beaverton, OR (US); Tejaswi K. Indukuri, Boise, ID (US)

(73) Assignee: Intel Corporation, Santa Clara, CA (US)

(21) Appl. No.: 16/082,261

(22) PCT Filed: Apr. 1, 2016
(86) PCT No.: PCT/US2016/025576

§ 371 Date: Sep. 4, 2018

(51) Int. Cl. H01L 27/1159; H01L 27/11587; H01L 29/78; G11C 11/22

(52) U.S. Cl. CPC H01L 27/1159; G11C 11/223; H01L 29/78391; H01L 27/11587

(57) ABSTRACT

A monocrystalline metal-oxide stack including a ferroelectric (FE) tunneling layer and a buffer layer is epitaxially grown on a growth substrate. A first polycrystalline metal electrode layer is deposited over the tunneling layer. A bonding material layer is further deposited over the electrode layer. The bonding material layer is then bonded to a material layer on a front or back side of a host substrate that further comprises a transistor cell. Once bonded, the growth substrate may be removed from the metal-oxide stack to complete a transfer of the metal-oxide stack from the growth substrate to the host substrate. A second polycrystalline metal electrode layer is then deposited over the exposed buffer layer, placing both electrodes in close proximity to the FE tunneling layer.

### BACKGROUND

Ferroelectric (FE) materials are polar materials with a spontaneous electric polarization that can be switched by an applied electric field. Some ferroelectric memory (FEM) architectures propose a ferroelectric tunneling junction (FTJ) in which a FE barrier is disposed between two metal electrodes. In such an FEM device, polarization within the ferroelectric material may be controlled to modulate tunneling current across the FTJ in a non-volatile manner. More or less conduction electrons can quantum-mechanically tunnel through the ferroelectric barrier as a function of polarization of the ferroelectric barrier. FEM is an attractive option for advanced electronic memory applications as spin-dependent transport properties may be controlled via a pure electronic mechanism known as the tunnel electroresistance (TER) effect. Tunnel magnetoresistance and magnetoelectric-resistance effects may also be significant in the operation of some FEM devices. With electrically induced polarization reversal, a FEM device may be laterally scaled to less than 25 nm and still display a change in resistance of 3-4 orders of magnitude, or more. As such, TER-based devices may offer the promise of greater scalability than do devices relying exclusively on the tunnel magnetoresistance (TMR) effect.

Successful use of FTJs in a FEM however is dependent on the FTJ having sufficient thermodynamic stability to hold a state. There are indications that nanostructural imperfections within the FE material layer, and at interfaces of that material layer, detract significantly from spontaneous polarization, resulting in lower junction stability. Hence, to form a FEM that fully leverages the TER effect, very precise high-temperature epitaxial film growths may be needed. It remains unclear how such high-quality ferroelectric material is to be provided in conjunction with operable transistors in a manufacturable memory bit-cell, and/or how such a memory could be embedded within a System-on-Chip (SoC) that further includes extensive logic (CMOS) circuitry.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a schematic of a FEM bit-cell, which includes a FTJ, in accordance with some embodiments of the present invention;

FIG. 2A is a cross-sectional view of a FTJ stack transferred to a front side of a substrate, in accordance with some FEM bit-cell embodiments;

FIG. 2B is a cross-sectional view of a FTJ stack transferred to a back side of a substrate, in accordance with some alternative FEM bit-cell embodiments;

FIG. 3 is a plan view of a FET, in accordance with some FEM bit-cell embodiments;

FIG. 4A is a cross-sectional view of a FET interconnected with a bonded FTJ, in accordance with some FEM bit-cell embodiments;

FIG. 4B is a cross-sectional view of a FET interconnected with a bonded FTJ, in accordance with some alternative FEM bit-cell embodiments;

FIG. 5 is a flow diagram illustrating methods for fabricating a FEM bit-cell, in accordance with some embodiments;

FIGS. 6A, 6B, and 6C illustrate cross-sectional views of epitaxial growth of a metal-oxide stack suitable for a FEM bit-cell, in accordance with some embodiments;

FIGS. 7A, 7B, 7C, 7D, and 7E illustrate cross-sectional views of a FEM bit-cell evolving as operations in the method illustrate in FIG. 5 are performed, in accordance with some embodiments;

FIGS. 8A, 8B, 8C, 8D, and 8E illustrate cross-sectional views of a FEM bit-cell evolving as operations in the method illustrate in FIG. 5 are performed, in accordance with some alternative embodiments;

FIG. 9 illustrates a mobile computing platform and a data server machine employing an SoC including a bonded FTJ, in accordance with embodiments; and

FIG. 10 is a functional block diagram of an electronic computing device, in accordance with some embodiments.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

FEM bit-cells and methods of fabricating such cells are described herein. In some embodiments, a FE tunneling layer of an FEM bit-cell is less than 2 nm in thickness. At such a low thickness, detecting a change in resistive state with a transistor poses a challenge. For example, even for a FTJ displaying a 10,000% difference in resistance between states, the resistance/area (RA) factor for 1 nm thick barrier may be around 10 Ω/μm². Such a resistance can detectable if there is a metal electrode sufficiently near the FE material. FE devices are grown on substrates that enable good FE crystal quality, but these substrates suffer from very large resistance as they are relatively poor conductors (e.g., semiconductors or insulators having a specific resistivity). Embodiments herein may reduce or eliminate the highly resistive crystals employed to growth of the FE barrier from the FTJ stack. The concomitant reduction in access resistance may improve FEM bit-cell performance.

In some embodiments, a monocrystalline metal-oxide stack including a ferroelectric barrier or “tunneling” layer and a buffer layer is epitaxially grown on a growth substrate. A first polycrystalline metal electrode layer is deposited over the tunneling layer. A bonding material layer is further deposited over the electrode layer. The bonding material layer is then bonded to a material layer on a front or back side of a host substrate that further comprises a transistor cell. The transistor cell may be part of the FEM bit-cell, for example the access transistor in a 1R-1T (1T1R) bit-cell. Alternatively, the transistor cell may be part of CMOS circuitry into which the FEM bit-cell is embedded, for example as part of a SoC. Once bonded, the growth substrate may be removed from the metal-oxide stack to complete a transfer of the metal-oxide stack from the growth substrate to the host substrate. The buffer layer is exposed during removal of the growth substrate, or subsequent to the removal. A second polycrystalline metal electrode layer is then deposited over the exposed buffer layer, placing both electrodes in close proximity to the FE tunneling layer. This second electrode layer may then be patterned and interconnected in any manner suitable for completion of the FEM bit-cell.

In some further embodiments, the above techniques are implemented to bond the FTJ stack to a front side or a back side of a transistor cell stratum. In such embodiments, the host substrate may include a carrier to which the transistor cell stratum has been bonded. An unbonded surface of the transistor cell stratum is further bonded to the FTJ stack during the metal-oxide stack transfer. In such embodiments, the FEM bit-cell may comprise a stack less than a few hundred microns in total thickness. In some embodiments, the transistor cell includes a deep via extending from a first side of a transistor semiconductor body to a second side of the transistor semiconductor body, opposite the first side. In some exemplary embodiments where the semiconductor body comprises a fin of semiconductor, the deep via extends the height of at least an active channel region of the fin, and advantageously extends an entire height of the semiconductor fin, including any sub-fin region below the active channel region. In some such embodiments, one end of the deep via makes electrical contact to at least one of the gate, source, or drain terminal of the transistor. A second end of the deep via makes electrical contact to one of the metal electrodes of the FTJ. Such contact may be through a metal layer employed to bond the FTJ to the transistor stratum.

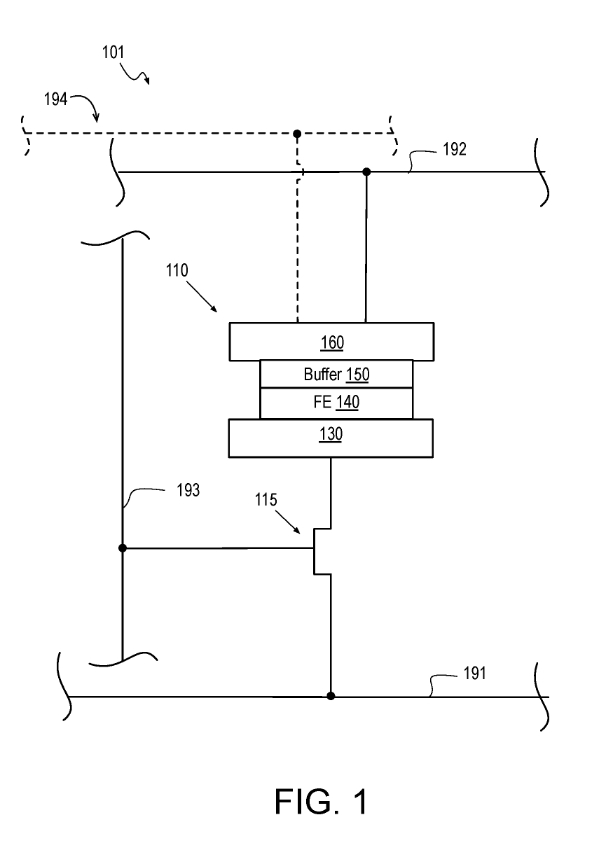

FIG. 1 is a schematic of a FEM bit-cell 101, which includes a bonded FTJ 110, in accordance with an embodiment of the present invention. The bonded FTJ 110 includes a ferroelectric tunneling layer 140 disposed between a metal electrode 130 proximate to the FE tunneling layer 140 and another metal electrode 160 that is proximate to a buffer layer 150. Metal electrode 160 is electrically coupled to a metal interconnect 192 (e.g., bit line). Metal electrode 130 is electrically connected to a metal interconnect 191 (e.g., source line) through a transistor 115. The transistor 115 is further connected to a third metal interconnect 193 (e.g., word line). The FEM bit-cell 101 may further include additional read and write circuitry (not shown), a sense amplifier (not shown), a bit line reference 194, and the like, as understood by those skilled in the art of non-volatile memory devices premised on resistance states. A plurality of the FEM bit-cell 101 may be operably connected to one another to form a FEM array (not shown), wherein the memory array can be incorporated into a non-volatile memory device or a SoC, etc.

FE tunneling layer 140 may be of any material known to have a ferroelectric phase and display the TER effect above some minimum operating temperature, such as room temperature (e.g., 25° C.). In some embodiments, FE tunneling layer 140 has perovskite crystal structure and is monocrystalline. The spontaneous polarization field of FE tunneling layer 140 may be aligned orthogonally to interfaces of FE tunneling layer 140. Exemplary FE tunneling layer materials include, but are not limited to, Bi₄Ti₃O₁₂, SrBi₂Ta2O₉, SrRuO₃, (Ba,Sr)TiO₃, BiMnO₃, BiFeO₃, PbTiO₃, and Pb(Zr,Ti)O₃. In some advantageous embodiments, FE tunneling layer 140 is BaTiO₃ (i.e., BTO). In some embodiments, FE tunneling layer 140 has a thickness less than 5 nm, advantageously less than 3 nm, and more advantageously less than 2 nm (e.g., 1-1.5 nm). For exemplary BTO embodiments, one perovskite unit cell is ˜0.4 nm, so the FE tunneling layer 140 may have a thickness as little as 2-3 BTO unit cells.

FE tunneling layer 140 is in direct contact with buffer layer 150. Buffer layer 150 may have many functions, such as, but not limited to, maintaining a high quality crystal interface with FE tunneling layer 140, setting a work function difference at the interface with FE tunneling layer 140, tuning strain within FE tunneling layer, and facilitating transfer of FE tunneling layer 140. In some embodiments, buffer layer 150 is part of the same single crystal as tunneling layer 140, but is of a different composition. For example, buffer layer 150 may also have perovskite crystal structure. In other embodiments, buffer layer 150 has different crystallinity than FE tunnel layer 140, such as cubic rather than tetragonal (perovskite). Buffer layer 150 need not be a FE material and may be a paraelectric, for example. In some embodiments, buffer layer 150 is of a material having a different lattice constant of than that of FE tunneling layer 140. In some embodiments, buffer layer 150 has a smaller lattice constant FE tunneling layer 140. The smaller lattice constant may beneficially strain the FE tunneling layer 140, advantageously increasing spontaneous polarization associated with the FTJ. For such embodiments, FE tunneling layer 140 may be pseudomorphically strained to match the lattice constant of buffer layer 150. Exemplary buffer layer materials include, but are not limited to, SrTiO₃, LaGaO₃, DyScO₃, GdScO₃, SmSCo₃, LaAlSrTi, and KTaO₃. In some advantageous embodiments where FE tunneling layer 140 is BTO, buffer layer 150 is (La, Sr)MnO₃ (i.e., LSMO), which also has perovskite crystal structure. Buffer layer 150 may be advantageously doped to reduce electrical resistivity, but in exemplary embodiments the specific resistivity of the material employed for buffer layer 150 is significantly higher the specific resistivity of metal electrodes 130, 160. Buffer layer 150 may also have a minimal thickness to minimize its electrical resistance contribution to bit-cell 101. In some embodiments, buffer layer 150 is no more than 100 nm, is advantageously less than 50 nm, and more advantageously less than 25 nm in thickness.

Metal electrode 130 may be any metallic material known to form an FTJ with FE tunneling layer 140. Metal electrode 130 is advantageously polycrystalline or amorphous, not monocrystalline. Polycrystalline metallization may have texture, with the population of crystal domains favoring a particular orientation relative to the crystal orientation of FE tunneling layer 140. Metal electrode 130 may be an elemental metal, an alloy thereof, an oxide, or a nitride thereof. Metal electrode 130 may have a specific resistivity less than half that of buffer layer 150. In some embodiments, metal electrode 130 is a ferromagnetic (FM) material, such as Co, Fe, or an alloy thereof. In alternative embodiments, metal electrode 130 is Pt, In₂O₃, or IrO₂, any of which may advantageously reduce the depolarization field. Although not bound by theory, it is currently understood that a depolarization field may result when polarization charges at the surface of FE tunneling layer 140 interfacing with metal electrode 130 are not fully compensated by free charge carriers. As such, the composition and microstructure of metal electrode 130 may have a significant impact on the FTJ. Metal electrode 130 may be of any thickness as electrical resistance of FEM bit-cell 101 will not be significantly impacted by metal electrode 130.

In some advantageous embodiments, metal electrode 160 is also polycrystalline or amorphous, not monocrystalline. Polycrystalline forms of metal electrode 160 may also have texture, with the population of crystal domains favoring a particular orientation relative to the crystal orientation of buffer layer 150. Metal electrode 160 may be an elemental metal, an alloy thereof, an oxide, or a nitride thereof. Metal electrode 160 may have a specific resistivity less than half that of buffer layer 150. In some embodiments, metal electrode 160 has a different composition than metal electrode 130. Although the composition of metal electrodes 130 and 160 may be the same, the choice of materials for metal electrode 160 is less constrained because metal electrode 160 interfaces with buffer layer 150 rather than FE tunneling layer 140. In some exemplary embodiments, metal electrode 160 is Co or Cu, or another metal of having a comparable specific resistivity. Metal electrode 160 may be of any thickness as the electrical resistance of FEM bit-cell 101 will not be significantly impacted by metal electrode 160.

Notably absent from FEM bit-cell 101 is any growth substrate upon which FE tunneling layer 140 was epitaxially grown. FEM bit-cell 101 therefore will not suffer high electrical resistance attributable to significant thicknesses of growth substrate material.

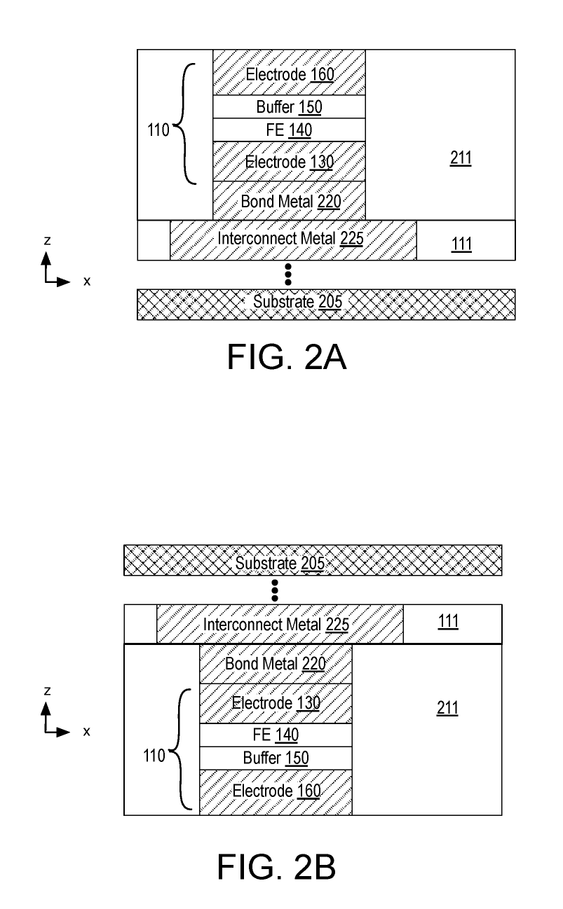

In some embodiments, a bonding material layer joins a metal electrode of an FTJ to a host substrate. The bonding material layer may be a metal, for example a noble metal, such as, but not limited to, Au. The bonding material layer may be in direct contact with a polycrystalline metal electrode of the FTJ and the bonding material layer may be in further contact with either a front side or back side of a host substrate. FIG. 2A is a cross-sectional view of a bonded FTJ 110 that has been transferred to a front side of a host substrate 205, in accordance with some FEM bit-cell embodiments. Bonding material layer 220 is in direct contact with metal electrode 130, proximal to FE tunneling layer 140. Bonding material layer 220 is in further contact with an interconnect metal layer 225, which may be any level within a multi-level backend interconnect stack disposed on a front side of host substrate 205. One or more dielectric materials 111, 211 are disposed around sidewalls of FTJ 110 and/or interconnect metal 225. FIG. 2B is a cross-sectional view of a bonded FTJ 110 that has been transferred to a back side of host substrate 205, in accordance with some alternative FEM bit-cell embodiments. Bonding material layer 220 is in contact with electrode 130, proximal to FE tunneling layer 140. Bonding material layer 220 is in further contact with interconnect metal layer 225. For such embodiments, interconnect metal layer 225 may be any level within a multi-level backend interconnect stack disposed on a back side of host substrate 205. Although front-side and back-side bonding embodiments are separately illustrated, it is also possible to combine these exemplary embodiments such that two FTJ are bonded to a host substrate with one FTJ bonded on a front side of the host and the other FTJ bonded to a back side of the host.

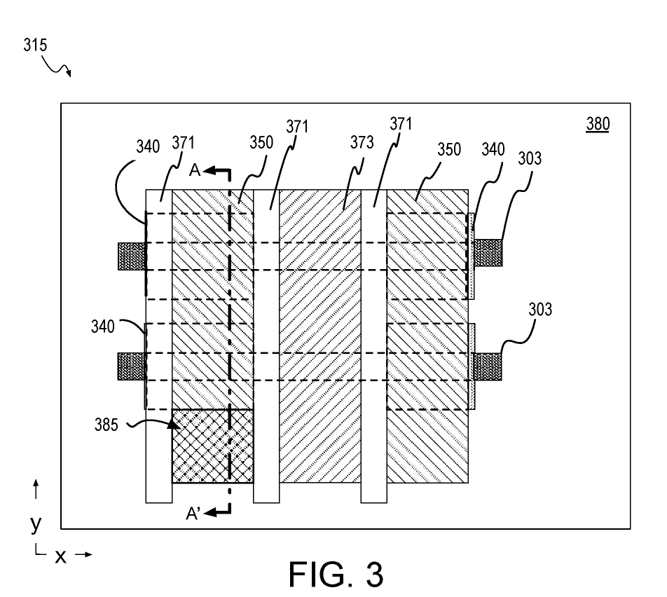

In some embodiments, a FEM bit-cell includes a FTJ bonded to a host substrate including a transistor cell. FIG. 3 is a top-side plan view of an exemplary field effect transistor (FET) cell 315, in accordance with some FEM bit-cell embodiments. In some exemplary embodiments, FET cell 315 is an implementation of FET 115 shown in FIG. 1. In other embodiments, a FET of similar structure is included in other CMOS circuitry on a host substrate that is integrated with a FEM bit-cell, but is not part of the FEM bit-cell.

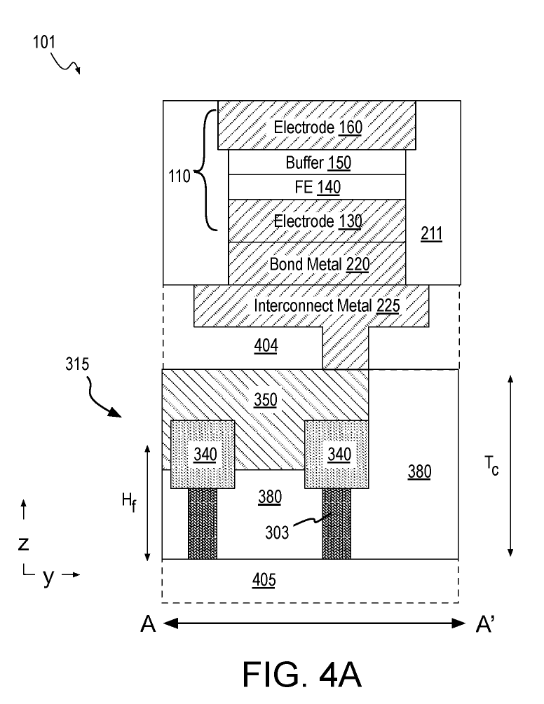

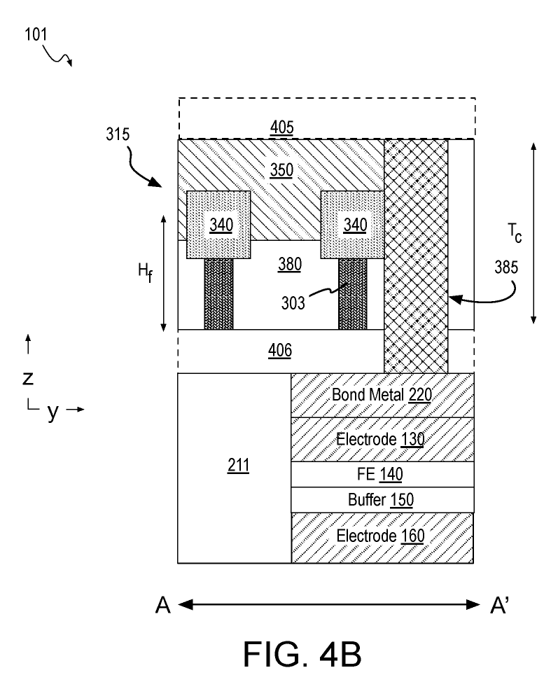

In FIG. 3, solid lines denote salient materials forming a top-side surface of a transistor cell stratum while dashed lines denote salient material interfaces within the transistor stratum that are disposed below another overlying material. The heavy dot-dashed A-A′ line denotes a plane along which cross-sectional views are further provided in FIGS. 4A and 4B. FET cell 315 includes semiconductor bodies 303 that are embedded within a dielectric isolation material 380. FET cell 315 further includes a gate electrode 373 strapping across a channel region of each of a first and a second semiconductor body 303. Although two semiconductor bodies 303 are illustrated in FIG. 3, a FET may include one or more semiconductor bodies. Semiconductor bodies 303 may have any semiconductor composition known to be suitable for a field effect transistor, such as, but not limited to, group IV materials (e.g., Si, Ge, SiGe), group III-V materials (e.g., GaAs, InGaAs, InAs, InP), or group III-N materials (e.g., GaN, AlGaN, InGaN). In some advantageous embodiments, semiconductor bodies 103 are monocrystalline.

Source and drain metallization 350 is disposed on opposite sides of gate electrode 373 and also extends across semiconductor bodies 303. In the illustrated embodiment, source/drain metallization 350 is disposed on a raised source/drain semiconductor 340, which is further disposed on semiconductor bodies 303. Source/drain semiconductor 340 may be heavily-doped with electrically active impurities imparting n-type or p-type conductivity. In some exemplary embodiments, both the source and drain semiconductor 340 is doped to the same conductivity type (e.g., n-type for NMOS and p-type for PMOS). In alternative embodiments (e.g., for a tunneling FET), the source/drain semiconductor 340 may be doped complementarily. Source/drain semiconductor 340 may be any semiconductor material compatible with semiconductor bodies 303, such as group IV materials (e.g., Si, Ge, SiGe), and/or group III-V materials (e.g., InGaAs, InAs).

An electrically insulating dielectric spacer 371 laterally separates gate electrode 373 from source/drain metallization 350 and/or source/drain semiconductor 340. Source/drain metallization 350 may include one or more metals, such as Ti, W, Pt, their alloys, and nitrides that form an ohmic or tunneling junction with doped-semiconductor terminals 340. In the illustrative embodiment, FET cell 315 further includes a deep via 385 that passes through the material thickness (e.g., z-dimension) occupied by FET cell 315. Dielectric spacer 371 also laterally separates gate electrode 373 from deep via 385. In the illustrative embodiment, deep via 385 is disposed between two stripes of dielectric spacer 371. Dielectric spacer 371 may be or any conventional dielectric such as, but not limited to, silicon dioxide, silicon nitride, or silicon oxynitride. Dielectric spacer 371 may also be any known low-k material having a relative permittivity below 4.0. Deep via 385 is at least partially filled with via metallization (e.g., Ti, W, Pt, their alloys, and nitrides).

FIG. 4A is a cross-sectional view of FEM bit-cell 101 along the A-A′ plane of FET cell 315 illustrated in FIG. 3. As shown, FET cell 315 is electrically interconnected with a bonded FTJ, in accordance with some embodiments. In this exemplary embodiment, FTJ 110 is bonded to a front side of FET cell 315 and electrically interconnected to transistor source/drain metallization 350 through bonding material layer 220. Bonding material layer 220 is in direct contact with interconnect metal 225. Although only a single interconnect metallization level is illustrated, interconnect metal 225 may be a top metallization level of a multi-level front-side interconnect stack 404. Front-side stack 404 may include, for example, 1-12 backend metallization levels embedded within interlayer dielectric and built up over FET cell 315.

In the illustrative embodiment, semiconductor bodies 103 have a z-height H_{f}, and transistor cell 315 has a thickness T_{c} as measured from a bottom, or back-side cell surface interfacing with a carrier 405. Front-side stack 404 and carrier 405 are illustrated in dashed line as not being part of the transistor cell stratum or FTJ and only provide a contextual reference illustrating what may be disposed between the FTJ and transistor cell and how FEM bit-cell 101 may be mechanically supported. Carrier 405 may be any known to be suitable for supporting a transistor cell strata. For example, carrier 405 may include one or more materials from which semiconductor bodies 303 were fabricated. For silicon semiconductor bodies, carrier 405 may include a crystalline group IV substrate, such as Si. For group III-V semiconductor bodies, carrier 405 may include a crystalline III-V material, such as GaAs, or a group IV substrate, such as Si. Alternatively, carrier 405 may include a material to which the stratum including transistor cell 315 was transferred (e.g., bonded), or which was deposited onto a back-side of cell 315, before or after FTJ 110 was bonded to the front side of the transistor stratum. For example, carrier 405 may include another transistor cell stratum, another FTJ, a polymer sheet, a plurality of thin films, or any other material(s) built up over a back side of semiconductor bodies 303.

FIG. 4B is a cross-sectional view of FEM bit-cell 101 long the A-A′ plane of FET cell 315 illustrated in FIG. 3. In this exemplary embodiment, FTJ 110 is bonded to a back side of FET cell 315 and electrically interconnected to transistor source/drain metallization 350 through bonding material layer 220. Bonding material layer 220 is in direct contact with deep via 385. Deep via 385 extends through the entire transistor cell thickness T_{c} with one end of the deep via metallization in contact with source/drain metallization 350 and another end of the deep via metallization in contact with bonding material layer 220. A back-side stack 406 may be disposed over a back-side of transistor cell 315. Deep via 385 may extend any depth into back-side stack 406 to intersect bonding material layer 220.

Transistor cell 315 is supported by carrier 405. Carrier 405 and back-side stack 406 are illustrated in dashed line as not being part of the transistor cell stratum or FTJ and only providing a contextual reference illustrating what deep via 385 may intersect, and how FEM bit-cell 101 may be mechanically supported. Carrier 405 may be any known to be suitable for supporting a transistor cell strata. In some embodiments, carrier 405 includes a material to which transistor cell 315 was transferred (e.g., bonded), or which was deposited onto a front-side of cell 315, before or after FTJ 110 was bonded to the back side. For example, carrier 405 may include another transistor cell stratum, another FTJ, a polymer sheet, a plurality of thin films, or any other material(s) built up over a front side of semiconductor bodies 303.

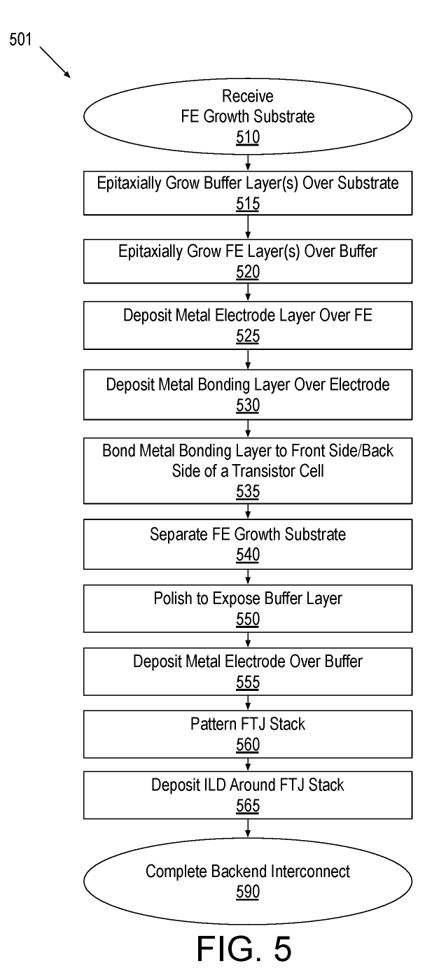

FEM bit-cells including a bonded FTJ, for example with one or more of the features described above, may be fabricated by a variety of methods applying a variety of techniques and processing chamber configurations. FIG. 5 is a flow diagram illustrating a method 501 for fabricating a FEM bit-cell including a bonded FTJ, in accordance with some illustrative embodiments. Method 501 begins with epitaxial growth of the monocrystalline metal-oxide stack on a growth substrate. This may be a blanket epitaxial growth performed at a wafer-level. At operation 510, a growth substrate suitable for epitaxially growing a monocrystalline metal-oxide stack including a FE material layer is received. At operation 515, a buffer layer is epitaxially grown over a surface of the growth substrate. At operation 520, a FE material layer is epitaxially grown over a surface of the buffer layer.

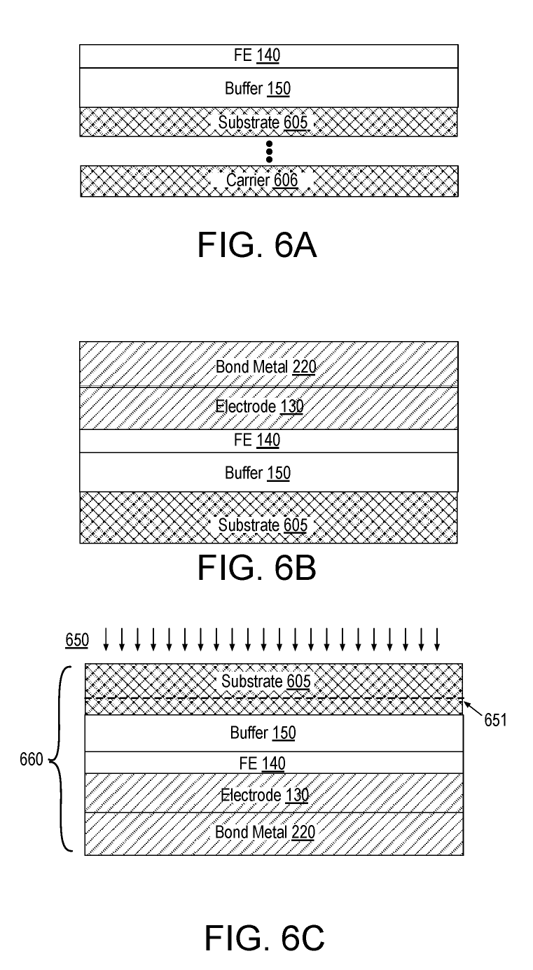

FIG. 6A illustrates a cross-sectional view of a metal-oxide layer growth stack, in accordance with some embodiments. In some embodiments, growth substrate 605 is a monocrystalline substrate. In some embodiments, growth substrate 605 is a heterostructure including one or more monocrystalline material layers. In some exemplary embodiments, growth substrate 605 has cubic crystal structure. In some further embodiments, growth substrate 605 has a lattice constant smaller than that of the FE material to be grown. In some exemplary embodiments, growth substrate 605 is NdGaO₃ (NGO). As substrates such as NGO may be of a smaller diameter than conventional silicon substrates, in some alternative embodiments growth substrate 605 is a layer of a heterostructure further comprising a large-format (e.g., 300-450 mm) carrier 606. Carrier 606 may be a monocrystalline silicon substrate, for example. Growth substrate 605 (e.g., NGO crystal) may have been previously epitaxially grown over carrier 606. Alternatively, multiple smaller format growth substrate chips may have been pick-and-placed onto carrier 606. The heterostructure may therefore have one or more material layers between substrate 605 and carrier 606.

Any epitaxial process known in the art to be suitable for a particular buffer layer may be employed to grow buffer layer 150 on a monocrystalline surface of growth substrate 605. In some embodiments, one or more of SrTiO₃, LaGaO₃, DyScO₃, GdScO₃, SmSCo₃, LaAlSrTi, KTaO₃, and LSMO is grown. In some embodiments where growth substrate 605 has cubic crystal structure, buffer layer 150 is epitaxially grown on a (001) surface of growth substrate 605. For exemplary embodiments where growth substrate 605 has a smaller lattice constant than buffer layer 150, buffer layer 150 may be grown pseudomorphically as a strained layer. Buffer layer 150 may also be grown as a fully relaxed film. Buffer layer 150 may be grown to a thickness of 25-100 nm, for example.

Any epitaxial process known in the art to be suitable for a particular ferroelectric tunneling layer may be employed to grow FE tunneling layer 140 on a surface of buffer layer 150. In some advantageous embodiments, the FE tunneling layer 140 has the same crystal structure as buffer layer 150, but a smaller lattice constant and is grown pseudomorphically as a monocrystalline material with in-plane strain. In some embodiments, one of Bi₄Ti₃O₁₂, SrBi₂Ta2O₉, SrRuO₃, (Ba,Sr)TiO₃, BiMnO₃, BiFeO₃, PbTiO₃, Pb(Zr,Ti)O₃ and BaTiO₃ is grown on a surface of buffer layer 150. FE tunneling layer 140 may be grown to a thickness of 2-5 nm, for example.

Returning to FIG. 5, method 501 continues with depositing one metal electrode layer on the FE material stack and preparing the stack for transfer from the growth substrate to a host substrate. At operation 525, a metal electrode layer is deposited over the FE tunneling layer. At operation 530, a bonding material layer is deposited over the metal electrode layer. Any deposition process known in the art to be suitable for the particular electrode and bonding material layers may be employed at operations 525, 530. In some embodiments, a metal electrode layer and metal bonding layer is deposited, for example by PVD. The metal layers deposited at operation 525 and 530 may be polycrystalline and have any desired thickness.

FIG. 6B illustrates a cross-sectional view of a metal electrode layer 130 deposited directly on a surface of FE tunneling layer 140, in accordance with some embodiments. Any deposition process known in the art to be suitable for the particular metal may be employed to deposit metal electrode layer 130. In some embodiments, one or more of Co, Fe, Pt, IrO₂, In₂O₃ is deposited by physical vapor deposition (PVD). Bonding material layer 220 (e.g., Au) is deposited directly on metal electrode layer 130. Bonding material layer 220 may be left as a wafer-level blanket film, or patterned into traces if a metal and oxide bonding process is to be performed. FIG. 6C further illustrates an FTJ substrate 660 that has further received a blanket implant 650 to promote a wafer-level fracture that will facilitate transfer of the partial FTJ stack to a host substrate. In some exemplary embodiments, a light element (e.g., H, He, or Li) is implanted to a uniform target depth 651 within growth substrate 605 where the fracture plane is desired.

With preparation of the epitaxial FTJ substrate substantially complete, method 501 proceeds with transfer of the partial FTJ stack from the FE growth substrate to a host substrate. Depending on the diameter of the FTJ substrate, one or more FTJ substrate may be joined with one host substrate. Referring again to FIG. 5, method 501 continues at operation 535 where the bonding layer is joined to a front or back of a transistor cell exposed on the host substrate. Operation 535 may entail any metal-to-metal or metal-to-metal and oxide-to-oxide) thermal-compression bonding process known in the art to be suitable for transfer of single crystal layers between two substrates.

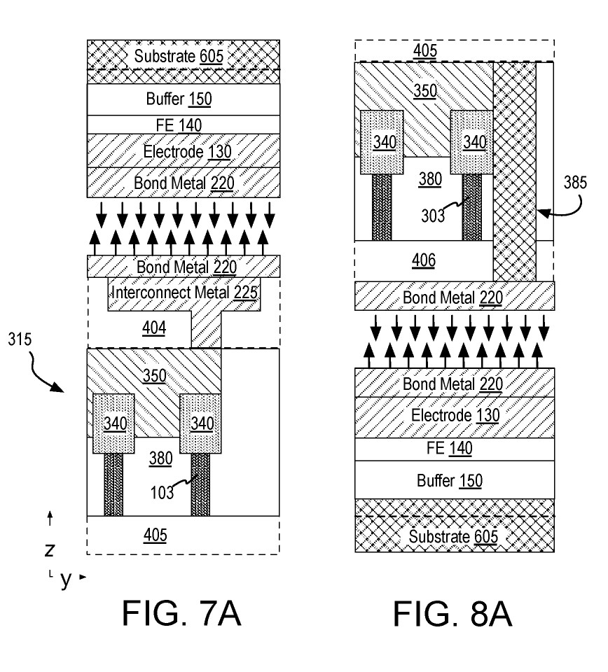

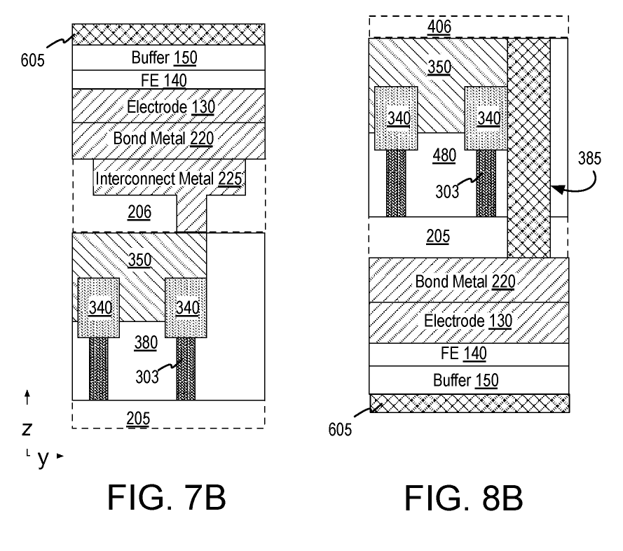

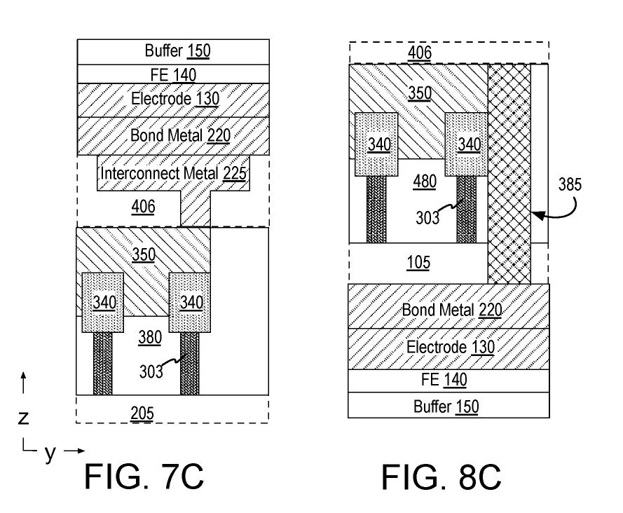

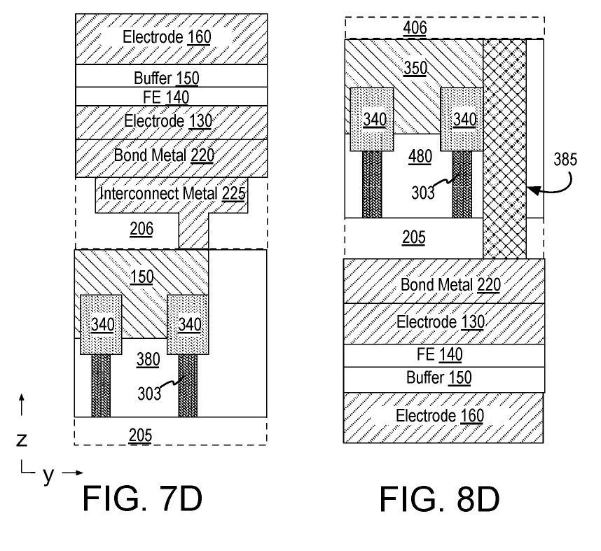

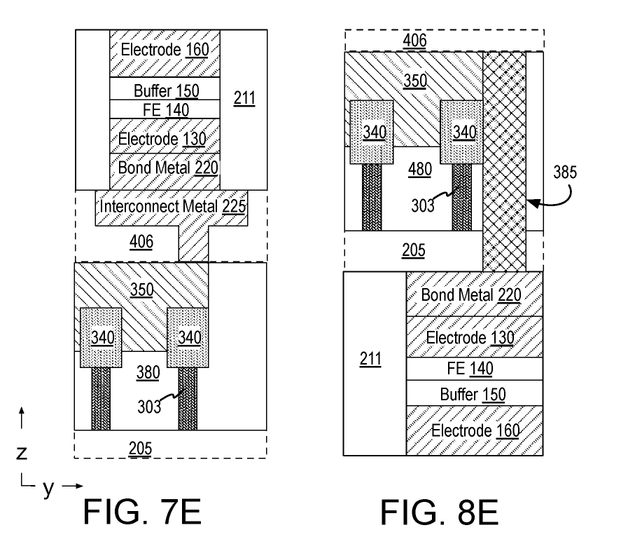

FIG. 7A illustrates a cross-sectional view of a partial FTJ stack joining a front side of transistor cell 315, in accordance with some embodiments. Bonding material layer 220 disposed on FTJ electrode 130 is brought into with bonding material layer 220 disposed on interconnect metal 225. FIG. 8A illustrates a cross-sectional view of a partial FTJ stack joining a back side of transistor cell 315, in accordance with some embodiments. As shown, bonding material layer 220 disposed on FTJ electrode 130 is contacted to a bonding material layer 220 disposed on deep via 385. The bonding material layers 220 may be the same (e.g., Au—Au). In some embodiments, processing of transistor cell 315 prior to bonding with the FTJ stack includes application of carrier 405 to a front side of the transistor stratum. A back-side substrate of transistor cell 315 may then be thinned into a back-side stack that includes bonding material layer 220 directly contacting deep via 385. Alternatively, the back-side substrate is complete removed and replaced with such a back-side stack. For example, any known grind, and/or polish, and/or layer transfer process may be employed to reveal a back side of deep via 385.

Returning to FIG. 5, method 501 continues at operation 540 where the FE growth substrate is separated from the partial FTJ stack. Separation may entail forming an in-plane fracture through the substrate or simply grinding and/or polishing away the substrate as sacrificial. In some exemplary embodiments where a fracture plane has been defined (e.g., by implantation of a species into the growth substrate), operation 540 may entail heating the bonded substrates to induce fracture within the implanted region. In some embodiments, the substrate is heated to 350-400° C. to disengage the growth substrate. As further illustrated in FIGS. 7B and 8B, following separation of substrate 605, the partial FTJ stack is supported by the host substrate including transistor cell 315. Following separation of the growth substrate, a partial thickness of growth substrate 605 remains, which is then ground or polished off at operation 550 (FIG. 5). With buffer layer 150 exposed, as further illustrated in FIGS. 7C and 8C, the partial FTJ stack is ready to receive a deposition of the second metal electrode.

Referring again to FIG. 5, method 501 continues at operation 555 where the second FTJ metal electrode layer is deposited. In the exemplary embodiment further illustrated in FIGS. 7D and 8D, metal electrode layer 160 is blanket deposited in direct contact with buffer layer 150. At operation 560 (FIG. 5), the FTJ stack is patterned, for example into an array of FTJ stacks with one FTJ stack for each transistor cell to form an array of 1R-1T FEM bit-cells. Patterning may be with any etch process(es) known to be suitable for the application. Etching of the FTJ stack may terminate upon clearing the bonding material layer 220. Interlayer dielectric material is then deposited over the FTJ stacks at operation 565 to arrive at the FEM bit-cell 101 illustrated in FIG. 7E, 8E and having structural features substantially as described above in the context of FIG. 4A, 4B. Method 501 (FIG. 5) is then completed at operation 590 where any additional interconnect metallization may be coupled to the second metal electrodes of the FTJ stacks.

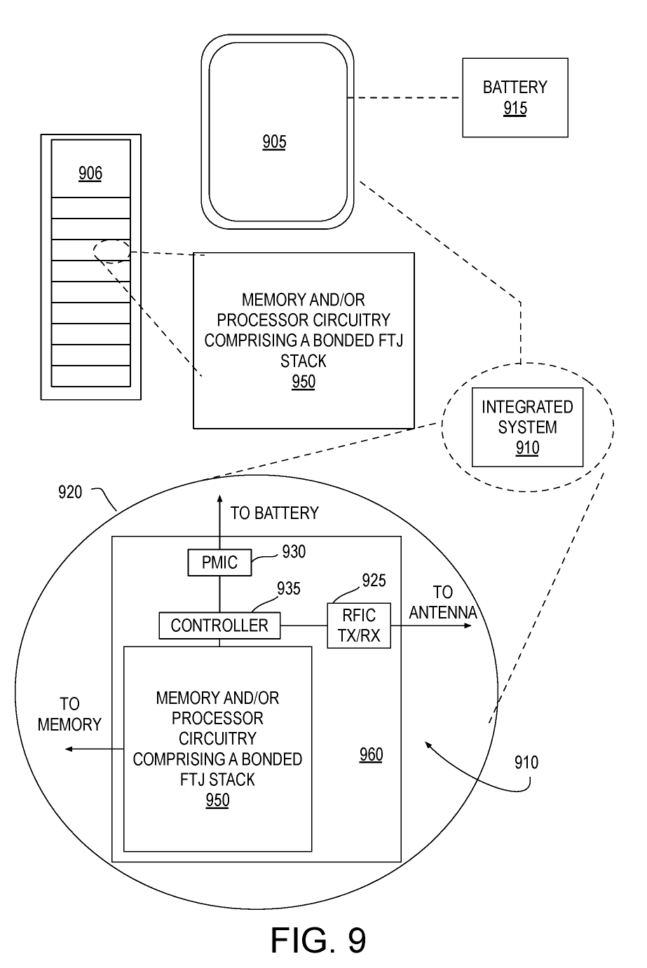

FIG. 9 illustrates a mobile computing platform and a data server machine employing a processor or memory including bonded FTJ stacks, for example as described elsewhere herein. The server machine 906 may be any commercial server, for example including any number of high-performance computing platforms disposed within a rack and networked together for electronic data processing, which in the exemplary embodiment includes a packaged monolithic SoC 950. The mobile computing platform 905 may be any portable device configured for each of electronic data display, electronic data processing, wireless electronic data transmission, or the like. For example, the mobile computing platform 905 may be any of a tablet, a smart phone, laptop computer, etc., and may include a display screen (e.g., a capacitive, inductive, resistive, or optical touchscreen), a chip-level or package-level integrated system 910, and a battery 915.

Either disposed within the integrated system 910 illustrated in the expanded view 920, or as a stand-alone packaged chip within the server machine 906, monolithic SoC 950 includes a memory block (e.g., RAM), a processor block (e.g., a microprocessor, a multi-core microprocessor, graphics processor, or the like) including at least one bonded FTJ stack, for example as described elsewhere herein. The monolithic SoC 950 may be further coupled to a board, a substrate, or an interposer 960 along with, one or more of a power management integrated circuit (PMIC) 930, RF (wireless) integrated circuit (RFIC) 925 including a wideband RF (wireless) transmitter and/or receiver (TX/RX) (e.g., including a digital baseband and an analog front end module further comprises a power amplifier on a transmit path and a low noise amplifier on a receive path), and a controller 935.

Functionally, PMIC 930 may perform battery power regulation, DC-to-DC conversion, etc., and so has an input coupled to battery 915 and with an output providing a current supply to other functional modules. As further illustrated, in the exemplary embodiment, RFIC 925 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond. In alternative implementations, each of these board-level modules may be integrated onto separate ICs or integrated into monolithic SoC 950.

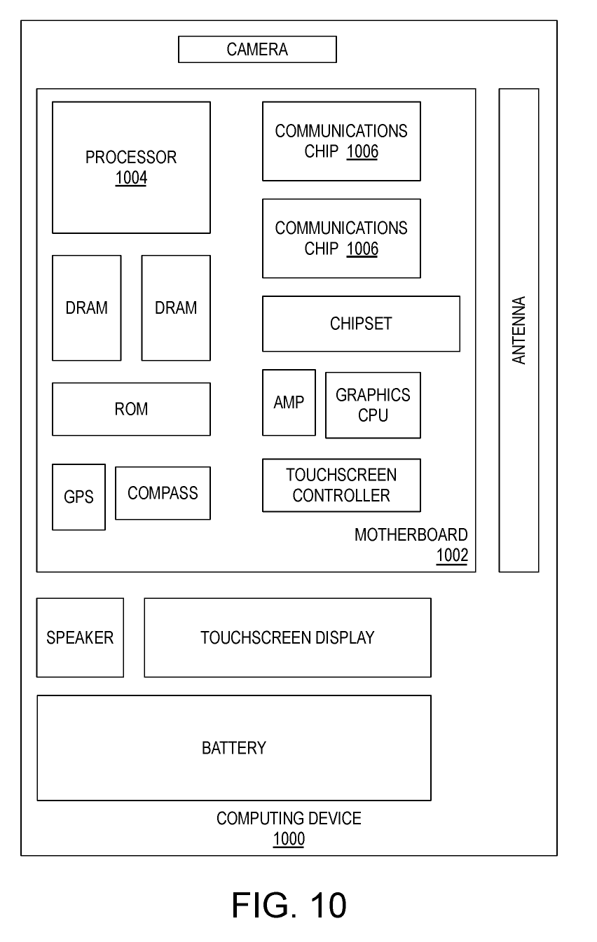

FIG. 10 is a functional block diagram of an electronic computing device, in accordance with some embodiments. Computing device 1000 may be found inside platform 1005 or server machine 1006, for example. Device 1000 further includes a motherboard 1002 hosting a number of components, such as, but not limited to, a processor 1004 (e.g., an applications processor), which may further incorporate at least one including bonded FTJ stack, for example as described elsewhere herein. Processor 1004 may be physically and/or electrically coupled to motherboard 1002. In some examples, processor 1004 includes an integrated circuit die packaged within the processor 1004. In general, the term “processor” or “microprocessor” may refer to any device or portion of a device that processes electronic data from registers and/or memory to transform that electronic data into other electronic data that may be further stored in registers and/or memory.

In various examples, one or more communication chips 1006 may also be physically and/or electrically coupled to the motherboard 1002. In further implementations, communication chips 1006 may be part of processor 1004. Depending on its applications, computing device 1000 may include other components that may or may not be physically and electrically coupled to motherboard 1002. These other components include, but are not limited to, volatile memory (e.g., DRAM), non-volatile memory (e.g., ROM), flash memory, a graphics processor, a digital signal processor, a crypto processor, a chipset, an antenna, touchscreen display, touchscreen controller, battery, audio codec, video codec, power amplifier, global positioning system (GPS) device, compass, accelerometer, gyroscope, speaker, camera, and mass storage device (such as hard disk drive, solid-state drive (SSD), compact disk (CD), digital versatile disk (DVD), and so forth), or the like.

Communication chips 1006 may enable wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1006 may implement any of a number of wireless standards or protocols, including but not limited to those described elsewhere herein. As discussed, computing device 1000 may include a plurality of communication chips 1006. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that principles of the disclosure are not limited to the embodiments so described, but can be practiced with modification and alteration without departing from the scope of the appended claims. For example the above embodiments may include specific combinations of features as further provided below.

In one or more first embodiments, a method of fabricating a ferroelectric memory (FEM) bit-cell includes epitaxially growing a monocrystalline metal-oxide stack including a ferroelectric (FE) tunneling layer and a buffer layer on a growth substrate, depositing a first metal electrode layer over the tunneling layer, depositing a bonding material layer over the electrode layer, bonding the bonding material layer to a bonding material layer disposed on a front or back side of a host substrate further comprising a transistor cell, removing the growth substrate from the metal-oxide stack to expose the buffer layer, and forming a second metal electrode layer over the buffer layer.

In furtherance of the first embodiments, epitaxially growing the metal-oxide stack further comprises epitaxially growing a perovskite crystal to a thickness of no more than 50 nm on a heterogeneous crystalline substrate. Depositing the first metal electrode layer further comprises depositing a polycrystalline metal electrode in direct contact with the FE tunneling layer. Depositing the bonding material layer further comprises depositing a metal in direct contact with the metal electrode.

In furtherance of the first embodiments immediately above, epitaxially growing the perovskite crystal further comprises growing the FE tunneling layer to a thickness less than 5 nm and in direct contact with a buffer layer having a smaller lattice constant than that of the tunneling layer.

In furtherance of the first embodiments, bonding the bonding material layer to the host substrate further comprises thermal-compression bonding. Removing the growth substrate further comprises cleaving or grinding off a partial thickness of the growth substrate, and polishing away the remaining thickness of the growth substrate to expose the buffer layer.

In furtherance of the first embodiments immediately above, the method further comprises blanket-implanting a species to a target depth within the growth substrate; and cleaving or grinding off the partial thickness of the growth substrate further comprises heating the bonded host and growth substrates to a temperature sufficient to form a fracture within the growth substrate proximate to the target depth.

In furtherance of the first embodiments immediately above, the growth substrate comprises NdGaO₃ (NGO). Growing the buffer layer further comprises growing LaSrMnO₃ (LSMO) on a surface of the NGO. Growing the tunneling layer further comprises growing BaTiO₃ (BTO) on a surface of the LSMO. Depositing the first metal electrode layer further comprises depositing at least one of Co, Pt, In₂O₃, or IrO₂ on a surface of the BTO. Depositing the bonding metal further comprises depositing Au on a surface of one of the FM material layers.

In furtherance of the first embodiments, the transistor cell further comprises a source semiconductor and a drain semiconductor separated by a channel semiconductor, a gate electrode stack including a gate electrode and a gate dielectric disposed over the channel semiconductor, and source/drain metallization in contact with the source and drain semiconductor and separated from the gate electrode by at least a first dielectric spacer. The host substrate further comprises a carrier bonded to a front side or back side of the transistor cell, the carrier being of a material distinct from that of the channel semiconductor.

In furtherance of the first embodiments immediately above, the carrier is bonded to a front side of the transistor cell. The transistor cell further comprises a deep via extending between a front-side and back-side of the transistor cell, a first end of the deep via being in contact with the source/drain metallization. Bonding the bonding material layer further comprises interconnecting a second end of the deep via with the first metal electrode layer.

In furtherance of the first embodiments, the carrier is bonded to a back side of the transistor cell, and bonding the bonding material layer further comprises interconnecting source/drain metallization with the first electrode material.

In one or more second embodiments, a ferroelectric memory (FEM) bit-cell comprises a host substrate including a transistor cell, and a ferroelectric tunneling junction (FTJ) bonded by a bonding layer to a front side or a back side of the host substrate. The FTJ further comprises a monocrystalline metal-oxide stack including a tunneling layer and a buffer layer, the stack disposed between a pair of polycrystalline metal electrode layers and having a thickness no more than 30 nm. The bonding layer electrically interconnects one of the pair of FTJ electrode layers to the transistor cell.

In furtherance of the second embodiments, the transistor cell further includes a source semiconductor and a drain semiconductor separated by a channel semiconductor, a gate electrode stack including a gate electrode and a gate dielectric disposed over the channel semiconductor, source/drain metallization in contact with the source and drain semiconductor and separated from the gate electrode by at least a first dielectric spacer, and one of the source/drain metallization is in electrical contact with one of the FTJ electrode layers through the bonding layer.

In furtherance of the second embodiments immediately above, the transistor cell further comprises a deep via extending through a thickness of the transistor cell, and the FTJ is bonded to a back side of the transistor cell, the bonding material layer in contact with the deep via.

In furtherance of the second embodiments, the buffer layer further comprises one of SrTiO₃, LaGaO₃, DyScO₃, GdScO₃, SmSCo₃, LaAlSrTi, and KTaO₃, and LaSrMnO₃. The tunneling layer further comprises one of Bi₄Ti₃O₁₂, SrBi₂Ta2O₉, SrRuO₃, (Ba,Sr)TiO₃, BiMnO₃, BiFeO₃, PbTiO₃, and Pb(Zr,Ti)O₃. At least the metal electrode layer proximal the FE tunneling layer comprises Co, Pt, In₂O₃, or IrO₂.

In furtherance of the second embodiments, the metal electrode layer proximal the buffer layer has a different composition that the metal electrode layer proximal the FE tunneling layer.

In furtherance of the second embodiments, the transistor cell further includes a source semiconductor and a drain semiconductor separated by a channel semiconductor. The host substrate further comprises a carrier bonded to a side of the transistor cell opposite the FTJ, and the carrier is a different material than the channel semiconductor.

In one or more third embodiments, a computer platform comprises a processor, a memory coupled to the processor, and a battery coupled to at least the processor, wherein at least one of the processor and memory further comprises one or more transistor strata including a field effect transistor (FET) cell, and one or more FTJ stack bonded to the transistor strata, wherein the FTJ stack further comprises a monocrystalline metal-oxide stack including a ferroelectric tunneling layer and a buffer layer, the stack disposed between a pair of polycrystalline metal electrode layers and having a thickness no more than 30 nm.

In furtherance of the third embodiments, the transistor cell further includes a source semiconductor and a drain semiconductor separated by a channel semiconductor, a gate electrode stack including a gate electrode and a gate dielectric disposed over the channel semiconductor, source/drain metallization in contact with the source and drain semiconductor and separated from the gate electrode by at least a first dielectric spacer, and a deep via extending through a thickness of the transistor cell and in contact with the source/drain metallization. The FTJ is bonded to a back side of the transistor cell, the bonding material layer is in contact with the deep via.

In furtherance of the third embodiments immediately above, a front side of one of the transistor strata is bonded to a carrier, the carrier being of a material distinct from that of the channel semiconductor.

In furtherance of the third embodiments, the buffer layer further comprises one of SrTiO₃, LaGaO₃, DyScO₃, GdScO₃, SmSCo₃, LaAlSrTi, and KTaO₃, and LaSrMnO₃. The tunneling layer further comprises one of Bi₄Ti₃O₁₂, SrBi₂Ta2O₉, SrRuO₃, (Ba,Sr)TiO₃, BiMnO₃, BiFeO₃, PbTiO₃, and Pb(Zr,Ti)O₃. At least the metal electrode layer proximal the FE tunneling layer comprises Co, Pt, In₂O₃, or IrO₂.

In furtherance of the third embodiments, the bonding material layer further comprises Au.

However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

1-20. (canceled)

21. A method of fabricating a ferroelectric memory (FEM) structure, the method comprising:
epitaxially growing a crystalline metal-oxide stack including a ferroelectric (FE) tunneling layer and a buffer layer on a growth substrate;
depositing a first metal electrode layer over the tunneling layer;
depositing a bonding material layer over the electrode layer;
bonding the bonding material layer to a bonding material layer on a front or back side of a host substrate further comprising a transistor structure;
removing the growth substrate from the metal-oxide stack to expose the buffer layer; and
forming a second metal electrode layer over the buffer layer.

22. The method of claim 21, wherein:
epitaxially growing the metal-oxide stack further comprises epitaxially growing a perovskite crystal to a thickness of no more than 50 nm on a heterogeneous crystalline substrate;
depositing the first metal electrode layer further comprises depositing a polycrystalline metal electrode in direct contact with the FE tunneling layer; and
depositing the bonding material layer further comprises depositing a metal in direct contact with the metal electrode.

23. The method of claim 22, where epitaxially growing the perovskite crystal further comprises growing the FE tunneling layer to a thickness less than 5 nm and in direct contact with a buffer layer having a smaller lattice constant than that of the tunneling layer.

24. The method of claim 22, wherein:
bonding the bonding material layer to the host substrate further comprises thermal-compression bonding; and
removing the growth substrate further comprises:
cleaving or grinding off a partial thickness of the growth substrate; and
polishing away a remaining thickness of the growth substrate to expose the buffer layer.

25. The method of claim 24, further comprising blanket-implanting a species to a target depth within the growth substrate; and
wherein cleaving or grinding off the partial thickness of the growth substrate further comprises heating the bonded host and growth substrates to a temperature sufficient to form a fracture within the growth substrate proximate to the target depth.

26. The method of claim 25, wherein:
the growth substrate comprises NdGaO₃ (NGO);
growing the buffer layer further comprises growing LaSrMnO₃ (LSMO) on a surface of the NGO;
growing the tunneling layer further comprises growing BaTiO₃ (BTO) on a surface of the LSMO; and
depositing the first metal electrode layer further comprises depositing at least one of Co, Pt, In₂O₃, or IrO₂ on a surface of the BTO; and
depositing the bonding metal further comprises depositing Au on a surface of one of the FM material layers.

27. The method of claim 21, wherein:
the transistor structure further comprises:
a source semiconductor and a drain semiconductor separated by a channel semiconductor;
a gate electrode stack including a gate electrode and a gate dielectric over the channel semiconductor; and
source and drain metallization in contact with corresponding ones of the source and drain semiconductor, and separated from the gate electrode by a spacer comprising a dielectric; and
the host substrate further comprises a carrier bonded to a front side or back side of the transistor structure, the carrier being of a material distinct from that of the channel semiconductor.

28. The method of claim 27, wherein:
the carrier is bonded to a front side of the transistor structure;
the transistor structure further comprises a via extending between a front-side and back-side of the transistor structure, a first end of the via in contact with an individual one of the source and drain metallization; and
bonding the bonding material layer further comprises interconnecting a second end of the via with the first metal electrode layer.

29. The method of claim 27, wherein:
the carrier is bonded to a back side of the transistor cell; and
bonding the bonding material layer further comprises interconnecting source/drain metallization with the first electrode material.

30. A ferroelectric memory (FEM) structure, comprising:
a host substrate including a transistor structure; and
a ferroelectric tunneling junction (FTJ) bonded by a bonding layer to a front side or a back side of the host substrate, wherein:
the FTJ further comprises a monocrystalline metal-oxide stack including a tunneling layer and a buffer layer, the stack between a pair of polycrystalline metal electrode layers and having a thickness no more than 30 nm; and
the bonding layer electrically interconnects one of the FTJ electrode layers to the transistor structure.

31. The FEM structure of claim 30, wherein:
the transistor structure further includes:
a source semiconductor and a drain semiconductor separated by a channel semiconductor;
a gate electrode stack including a gate electrode and a gate dielectric over the channel semiconductor;
source and drain metallization in contact with corresponding ones of the source and drain semiconductor, and separated from the gate electrode by at least a spacer comprising a dielectric; and
one of the source and drain metallization is in electrical contact with one of the pair of FTJ electrode layers through the bonding layer.

32. The FEM structure of claim 31, wherein:
the transistor structure further comprises a via extending through a thickness of the transistor structure; and
the FTJ is bonded to a back side of the transistor structure, the bonding material layer in contact with the via.

33. The FEM structure of claim 30, wherein:
the buffer layer further comprises one of SrTiO₃, LaGaO₃, DyScO₃, GdScO₃, SmSCo₃, LaAlSrTi, and KTaO₃, and LaSrMnO₃;
the tunneling layer further comprises one of Bi₄Ti₃O₁₂, SrBi₂Ta2O₉, SrRuO₃, (Ba,Sr)TiO₃, BiMnO₃, BiFeO₃, PbTiO₃, and Pb(Zr,Ti)O₃; and
at least the metal electrode layer proximal the FE tunneling layer comprises Co, Pt, In₂O₃, or IrO₂.

34. The FEM structure of claim 31, wherein the metal electrode layer proximal the buffer layer has a different composition that the metal electrode layer proximal the FE tunneling layer.

35. The FEM structure of claim 30, wherein:
the transistor structure further includes a source semiconductor and a drain semiconductor separated by a channel semiconductor;
the host substrate further comprises a carrier bonded to a side of the transistor structure opposite the FTJ; and
the carrier is a different material than the channel semiconductor.

36. A computer platform, comprising:
a processor;
a memory coupled to the processor; and
a battery coupled to at least the processor, wherein at least one of the processor and memory further comprises:
one or more transistor strata including a field effect transistor (FET) structure; and
one or more FTJ stack bonded to the transistor strata, wherein the FTJ stack further comprises a monocrystalline metal-oxide stack including a ferroelectric tunneling layer and a buffer layer, the stack disposed between a pair of polycrystalline metal electrode layers and having a thickness no more than 30 nm.

37. The computer platform of claim 36, wherein:
the transistor structure further includes:
a source semiconductor and a drain semiconductor separated by a channel semiconductor;
a gate electrode stack including a gate electrode and a gate dielectric over the channel semiconductor;
source and drain metallization in contact with corresponding ones of the source and drain semiconductor, and separated from the gate electrode by at least a spacer comprising a dielectric; and
a via extending through a thickness of the transistor structure and in contact with an individual one of the source and drain metallization; and
the FTJ is bonded to a back side of the transistor structure, the bonding material layer in contact with the via.

38. The platform of claim 37, wherein a front side of one of the transistor strata is bonded to a carrier, the carrier being of a material distinct from that of the channel semiconductor.

39. The platform of claim 36, wherein:
the buffer layer further comprises one of SrTiO₃, LaGaO₃, DyScO₃, GdScO₃, SmSCo₃, LaAlSrTi, and KTaO₃, and LaSrMnO₃;
the tunneling layer further comprises one of Bi₄Ti₃O₁₂, SrBi₂Ta2O₉, SrRuO₃, (Ba,Sr)TiO₃, BiMnO₃, BiFeO₃, PbTiO₃, and Pb(Zr,Ti)O₃; and
at least the metal electrode layer proximal the FE tunneling layer comprises Co, Pt, In₂O₃, or IrO₂.

40. The platform of claim 36, wherein the bonding material layer further comprises Au.
